(19) United States
(12) Patent Application Publication
(10) Pub. No.: US 2021/0328196 A1
(43) Pub. Date: Oct. 21, 2021

(54) OLED DISPLAY STRUCTURE AND OLED DISPLAY SCREEN

(71) Applicant: Wuhan China Star Optoelectronics Semiconductor Display Technology Co., Ltd., Wuhan, Hubei (CN)

(72) Inventors: Haoran Cao, Wuhan, Hubei (CN); Chihming Hsu, Wuhan, Hubei (CN)

(21) Appl. No.: 16/499,602

(22) PCT Filed: Aug. 2, 2018
(86) PCT No.: PCT/CN2018/098220

§ 371 Date: Sep. 30, 2019

(30) Foreign Application Priority Data
May 10, 2018 (CN) 201810443178.1

(51) Int. Cl. H01L 51/52; H01L 27/32

(52) U.S. Cl. CPC H01L 51/5281; H01L 27/3276; H01L 27/323

(57) ABSTRACT

An organic light emitting diode (OLED) display structure and an OLED display screen are disclosed. The OLED display structure includes: a display panel including a display region and a non-display region including a connection region and a plurality of clearance regions; a polarizer covering the display region; a chip on film (COF) circuit board assembly having a connection portion covering the connection region to electrically connect to the display panel, a plurality of gaskets covering the clearance region, and a functional assembly disposed over the polarizer, the connection portion and the gaskets.

### FIELD OF INVENTION

The present disclosure relates to the field of liquid crystal display, and specifically to an organic light emitting diode (OLED) display structure and an OLED display screen.

### BACKGROUND OF INVENTION

Compared with thin field transistor liquid crystal display (TFT-LCD) panels, active-matrix organic light-emitting diode (AMOLED) panels have some advantages such as low thickness, wide color gamut, and high contrast, and are mainly used for high-end small-size screens. However, at present, design and production for flexible AMOLED panel module are still not mature, since AMOLEDs require only one circular polarizer. In flexible AMOLEDs, they have no glass substrate with a cell structure compared with TFT-LCDs, and the panel itself is thinly cut and soft. Thus, polarizer (POL) mismatch occurs at a connecting position between a display panel and a chip on film (COF) board. It affects reliability of the display panel, and causes bad effects such as touch panel (TP) bonding or even 3D glass cover bonding, which may cause problems, such as a decrease in yield when the COF is connected.

Therefore, the prior art has drawbacks and is in urgent need of improvement.

### SUMMARY OF INVENTION

The present disclosure provides an organic light emitting diode (OLED) display structure and an OLED display screen, which have an effect of avoiding a decrease in yield that may cause at a COF press-fit connection.

The present disclosure provides an OLED display structure, which includes:
a display panel including a display region and a non-display region, wherein the non-display region includes a connection region and a plurality of clearance regions located on two sides of the connection region;
a polarizer covering the display region;
a chip on film (COF) circuit board assembly having a connection portion, wherein the connection portion covers the connection region to electrically connect to the display panel;
a plurality of gaskets covering the clearance regions; and
a functional assembly disposed over the polarizer, the connection portion, and the gaskets;
wherein each of the gaskets includes a polyethylene terephthalate (PET) material and a pressure sensitive adhesive (PSA); and wherein the functional assembly includes a first adhesive layer and a functionality layer adhered to the polarizer via the first adhesive layer.

In the OLED display structure of the present disclosure, the first adhesive layer overlaps with the polarizer, and a thickness of each of the gaskets is greater than or equal to a sum of a thickness of the first adhesive layer and a thickness of the polarizer.

In the OLED display structure of the present disclosure, the first adhesive layer is provided with a notch, wherein the first adhesive layer directly faces the connection region and the clearance regions, and the notch directly faces the connection portion, and a thickness of each of the gaskets is equal to a thickness of the polarizer.

In the OLED display structure of the present disclosure, the first adhesive layer directly faces the display panel and a thickness of each of the gaskets is equal to a thickness of the polarizer.

In the OLED display structure of the present disclosure, the functionality layer includes a touch function layer and/or an optic function layer.

In the OLED display structure of the present disclosure, the polarizer is a circular polarizer.

In the OLED display structure of the present disclosure, the display panel includes:
a substrate;
a thin film transistor (TFT) array layer disposed on the substrate;
an electroluminescence (EL) layer disposed on the TFT array layer; and
a packaging layer disposed on the EL layer.

The present disclosure also provides an OLED display structure, which includes:
a display panel including a display region and a non-display region, wherein the non-display region comprises a connection region and a plurality of clearance regions located on two sides of the connection region;
a polarizer covering the display region;
a chip on film (COF) circuit board assembly having a connection portion, wherein the connection portion covers the connection region to electrically connect to the display panel;
a plurality of gaskets covering the clearance regions; and
a functional assembly disposed over the polarizer, the connection portion, and the gaskets.

In the OLED display structure of the present disclosure, each of the gaskets includes a polyethylene terephthalate (PET) material and a pressure sensitive adhesive (PSA).

In the OLED display structure of the present disclosure, the functional assembly includes a first adhesive layer and a functionality layer adhered to the polarizer via the first adhesive layer.

In the OLED display structure of the present disclosure, the first adhesive layer overlaps with the polarizer, and a thickness of each of the gaskets is greater than or equal to a sum of a thickness of the first adhesive layer and a thickness of the polarizer.

In the OLED display structure of the present disclosure, the first adhesive layer is provided with a notch, wherein the first adhesive layer directly faces the connection region and the clearance regions, and the notch directly faces the connection portion, and a thickness of each of the gaskets is equal to a thickness of the polarizer.

In the OLED display structure of the present disclosure, the first adhesive layer directly faces the display panel and a thickness of each of the gaskets is equal to a thickness of the polarizer.

In the OLED display structure of the present disclosure, the functionality layer comprises a touch function layer and/or an optic function layer.

In the OLED display structure of the present disclosure, the polarizer is a circular polarizer.

In the OLED display structure of the present disclosure, the display panel includes:
a substrate;
a thin film transistor (TFT) array layer disposed on the substrate;
an electroluminescence (EL) layer disposed on the TFT array layer; and
a packaging layer disposed on the EL layer.

An organic light emitting diode (OLED) display screen including an OLED display structure, wherein the OLED display structure includes:
a display panel including a display region and a non-display region, wherein the non-display region comprises a connection region and a plurality of clearance regions located on two sides of the connection region;
a polarizer covering the display region;
a chip on film (COF) circuit board assembly having a connection portion, wherein the connection portion covers the connection region to electrically connect to the display panel; a plurality of gaskets covering the clearance regions; and
a functional assembly disposed over the polarizer, the connection portion, and the gaskets.

In the OLED display screen of the present disclosure, each of the gaskets comprises a polyethylene terephthalate (PET) material and a pressure sensitive adhesive (PSA).

In the OLED display screen of the present disclosure, the functional assembly includes a first adhesive layer and a functionality layer adhered to the polarizer via the first adhesive layer.

In the OLED display screen of the present disclosure, the first adhesive layer overlaps with the polarizer, and a thickness of each of the gaskets is greater than or equal to a sum of a thickness of the first adhesive layer and a thickness of the polarizer.

It may be seen from the above, the present disclosure prevents an occurrence of a mismatch at the clearance region of the display panel, thereby avoiding an effect to a touch function layer bonding or a glass cover bonding, and avoiding problems such as reductions in yield that may cause at a COF press-fit connection, by providing the gaskets at the clearance regions of the display panel.

### BRIEF DESCRIPTION OF DRAWINGS

In order to more clearly illustrate the technical solutions in the embodiments of the present disclosure, the drawings used in the description of the embodiments will be briefly described below. It is obvious that the drawings in the following description are only some embodiments of the present disclosure. Other drawings can also be obtained from those skilled in the art based on these drawings without paying any creative effort.

FIG. 1 is a schematic structural diagram of an organic light emitting diode (OLED) display structure in some embodiments of the present disclosure.

FIG. 2 is a structural diagram of a display panel of an OLED display structure according to an embodiment of the present disclosure.

FIG. 3 is one structural diagram of a first adhesive layer of a functional assembly of an OLED display structure in an embodiment of the present disclosure.

FIG. 4 is another one structural diagram of a first adhesive layer of a functional assembly of an OLED display structure in an embodiment of the present disclosure.

FIG. 5 is another one structural diagram of a first adhesive layer of a functional assembly of an OLED display structure in an embodiment of the present disclosure.

FIG. 6 is a schematic structural diagram of an OLED display screen according to some embodiments of the present disclosure.

### DETAILED DESCRIPTION OF PREFERRED EMBODIMENTS

The embodiments of the present disclosure are described in detail below, and the examples of the embodiments are illustrated in the drawings, wherein the same or similar reference numerals indicate the same or similar elements or elements having the same or similar functions. The embodiments described below with reference to the drawings are intended to be illustrative of the disclosure and are not to be construed as a limiting.

In the description of the present disclosure, it is to be understood that the terms such as “center”, “longitudinal”, “transverse”, “length”, “width”, “thickness”, “upper”, “lower”, “front”, “post”, “left”, “right”, “vertical”, “horizontal”, “top”, “bottom”, “inside”, “outside”, “clockwise”, “counterclockwise”, etc. indicate a relationship of orientations or a positions based on an orientation or positional relationship shown in the drawings, and that is merely for the convenience of the description of the present disclosure and the simplified description, rather than indicate or imply that the devices or components are referred to has a specific orientation or are constructed and operated in a specific orientation. Therefore, it should not be construed as limiting of the present disclosure. Moreover, the terms “first” and “second” are used for descriptive purposes only and are not to be construed as indicating or implying a relative importance or implicitly indicating the number of technical features indicated. Thus, features defining “first” or “second” may include one or more of the described features either explicitly or implicitly. In the description of the present disclosure, the meaning of “a plurality” is two or more unless otherwise specifically defined.

In the description of the present disclosure, it should be noted that the terms “installation”, “interconnection”, and “connection” are to be understood broadly, such as may be fixed, or detachable, or integral; may be mechanically connected, or may be electrically connected, or may communicate with each other; may be directly connected or indirectly connected through an intermediate medium, may be internal communication of two elements or interaction of two elements relationship. The specific meanings of the above terms in the present disclosure may be understood by those skilled in the art based on a specific situation.

In the present disclosure, unless otherwise specifically regulated and defined, the first feature “over” or “under” the second feature may include a direct contact of the first and second features, and may also include the first and second features that are not in a direct contact but through additional features between the first and second features. Moreover, the first feature “above”, “over” and “upper” the second feature includes the first feature directly above and above the second feature, or merely indicating that the first feature level is higher than the second feature. The first feature “below”, “under” and “lower” the second feature includes the first feature directly below and below the second feature, or merely indicating that the first feature level is less than the second feature.

The following disclosure provides many different embodiments or examples for implementing different structures of the present disclosure. In order to simplify the disclosure of the present disclosure, the components and arrangements of the specific examples are described below. Of course, they are merely examples and are not intended to limit the present disclosure. In addition, the present disclosure may be repeated with reference to the numerals and/or reference numerals in the various examples, which are for the purpose of simplicity and clarity, and do not indicate the relationship between the various embodiments and/or arrangements discussed. Moreover, the present disclosure provides examples of various specific processes and materials, but one of ordinary skill in the art will recognize the use of other processes and/or the use of other materials.

Please refer to FIG. 1, which is a schematic structural diagram of an OLED display structure according to some embodiments of the present disclosure. The OLED display structure includes a display panel 30, a polarizer 40, a COF (chip on film) circuit board assembly 50, a plurality of gaskets 60, and a functional assembly 70.

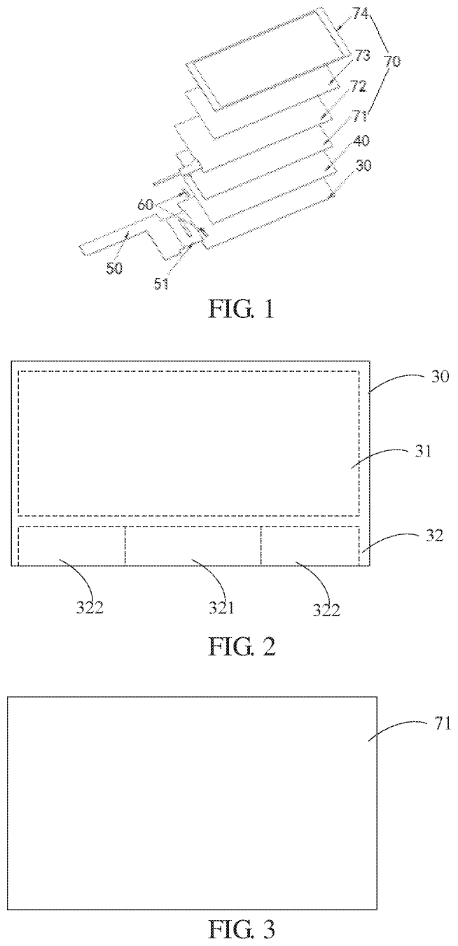

The display panel 30 is an active-matrix organic light-emitting diode (AMOLED) display panel. Meanwhile, referring to FIG. 2, the display panel 30 includes a display region 31 and a non-display region 32 arranged side by side. The non-display region 32 includes a connection region 321 and a plurality of clearance regions 322 located on two sides of the connection region. The display panel 30 has a substantially rectangular plate shape. The display region 31 and the non-display region 32 are both shaped as rectangular.

As viewed in a vertical direction, the display panel 30 includes a substrate, a thin film transistor (TFT) array layer disposed on the substrate, an electroluminescence (EL) layer disposed on the TFT array layer, and a packaging layer disposed on the EL layer. Of course, it is not limited to this hierarchical structure. The substrate is made of polyimide I) and has a thickness of about 10 microns.

The polarizer 40 is a circular polarizer. The polarizer 40 covers the display region 31 of the display panel 30.

The COF circuit board assembly 50 has a connection portion 51 covering the connection region 321 of the display panel 30 to electrically connect to the display panel 30. The COF circuit board assembly is a flexible circuit board, which provides with a driving chip for driving the display panel 30 and/or a touch function layer.

The gaskets 60 may cover the clearance regions 322 on the display panel 30. Each of the gaskets includes a polyethylene terephthalate (PET) material and a pressure sensitive adhesive (PSA).

The functional assembly 70 is disposed over the polarizer 40. The functional assembly 70 includes a first adhesive layer 71 and a functionality layer adhered to the polarizer 40 via the first adhesive layer 71. The functionality layer includes a touch function layer and/or an optic function layer. In some embodiments, the functionality layer includes a touch function layer 72, an optical function layer 73, and a protective film layer 74. Of course, the structure of the functionality layer is not limited thereto, and may be adjusted according to actual needs.

In some embodiments, referring to FIG. 3, the first adhesive layer 71 may overlap with the polarizer 40, that is, the area of the first adhesive layer 71 is substantially the same as the area of the polarizer 40, and may have certain tolerances. At this point, a thickness of each of the gaskets 60 is greater than or equal to a sum of a thickness of the first adhesive layer 71 and a thickness of the polarizer 40. Of course, the thickness of each of the gaskets 60 is most preferably equal to the sum of the thickness of the first adhesive layer 71 and the thickness of the polarizer 40.

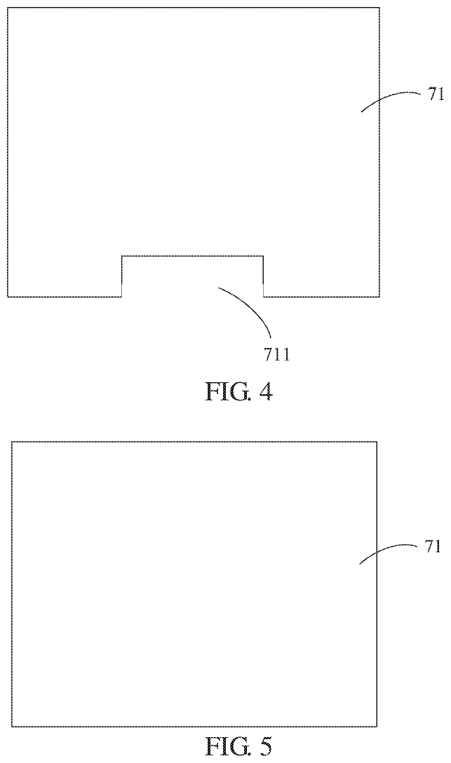

In some embodiments, referring to FIG. 4, the first adhesive layer 71 is provided with a notch 711, wherein the first adhesive layer 71 directly faces the connection region 321 and the clearance regions 322, and the notch 711 directly faces the connection portion 51 to expose the clearance regions 322. At this point, a thickness of each of the gaskets 60 is equal to a thickness of the polarizer 40.

In some embodiments, referring to FIG. 5, the first adhesive layer 71 directly faces the display panel, or the first adhesive layer 71 has substantially a same area as the display panel; a thickness of each of the gaskets 60 is equal to a thickness of the polarizer 40. The first adhesive layer 71 completely covers each of the gaskets 60 and the polarizer 40.

In some embodiments, each of the gaskets 60 completely covers a portion of the non-display region 32 of the display panel 30 except the connection region 321.

It may be seen from the above, the present disclosure prevents an occurrence of a mismatch at the clearance region of the display panel, thereby avoiding an effect to a touch function layer bonding or a glass cover bonding, and avoiding problems such as reductions in yield that may cause at a COF press-fit connection, by providing the gaskets at the clearance regions of the display panel.

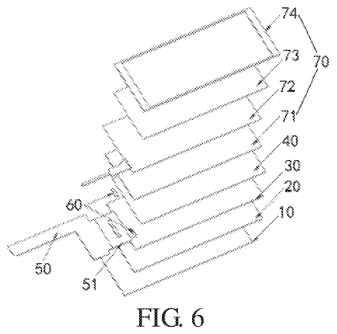

Referring to FIG. 6, the present disclosure also provides an OLED display panel comprising a biodegradable plastic (BP) layer 10, a second adhesive layer 20, a display panel 30, a polarizer 40, a COF circuit board assembly 50, a plurality of gaskets 60, and a functional assembly 70. In some embodiments, the OLED display further includes a housing and an electrically control assembly. The BP layer 10 is disposed on the housing. The electrically control assembly is disposed in the housing, and the electrically control assembly is electrically connected to the COF circuit board assembly 50.

The display panel 30 is connected to the BP layer 10 via the second adhesive layer 20. The BP layer is made of polyterephthalic plastic. The second adhesive layer 20 may be a PSA layer, wherein the PSA is an abbreviation of a pressure sensitive adhesive.

The display panel 30 is an AMOLED display panel. Meanwhile, referring to FIG. 2, as viewed in the horizontal direction, the display panel 30 includes a display region 31 and a non-display region 32 arranged side by side, wherein the non-display region 32 includes a connection region 321 and a plurality of clearance regions 322 located on two sides of the connection region. The display panel 30 has a substantially rectangular plate shape. The display region 31 and the non-display region 32 are both shaped as rectangular.

As viewed in a vertical direction, the display panel 30 includes a substrate, a thin film transistor (TFT) array layer disposed on the substrate, an electroluminescence (EL) layer disposed on the TFT array layer, and a packaging layer disposed on the EL layer. Of course, it is not limited to this hierarchical structure. The substrate is made of polyimide I) and has a thickness of about 10 microns.

The polarizer 40 is a circular polarizer. The polarizer 40 covers the display region 31 of the display panel 30.

The COF circuit board assembly 50 has a connection portion 51 covering the connection region 321 of the display panel 30 to electrically connect to the display panel 30. The COF circuit board assembly is a flexible circuit board, which provides with a driving chip for driving the display panel 30 and/or a touch function layer.

The gaskets 60 may cover the clearance regions 322 on the display panel 30. Each of the gaskets includes a polyethylene terephthalate (PET) material and a pressure sensitive adhesive (PSA).

The functional assembly 70 is disposed over the polarizer 40. The functional assembly 70 includes a first adhesive layer 71 and a functionality layer adhered to the polarizer 40 via the first adhesive layer 71. The functionality layer includes a touch function layer and/or an optic function layer. In some embodiments, the functionality layer includes a touch function layer 72, an optical function layer 73, and a protective film layer 74. Of course, the structure of the functionality layer is not limited thereto, and may be adjusted according to actual needs.

In some embodiments, referring to FIG. 3 simultaneously, the first adhesive layer 71 overlaps with the polarizer 40, that is, the area of the first adhesive layer 71 is substantially the same as the area of the polarizer 40, and may have certain tolerances. At this point, a thickness of each of the gaskets 60 is greater than or equal to a sum of a thickness of the first adhesive layer 71 and a thickness of the polarizer 40. Of course, the thickness of each of the gaskets 60 is preferably equal to the sum of the thickness of the first adhesive layer 71 and the thickness of the polarizer 40.

In some embodiments, referring to FIG. 4, the first adhesive layer 71 is provided with a notch 711, the first adhesive layer 71 directly faces the connection region 321 and the clearance regions 322, the notch 711 directly faces the connection portion 51. At this point, a thickness of each of the gaskets 60 is equal to a thickness of the polarizer 40.

In some embodiments, referring to FIG. 5, the first adhesive layer 71 directly faces the display panel, in other words, they have substantially the same area; a thickness of each of the gaskets 60 is equal to a thickness of the polarizer 40. The first adhesive layer 71 completely covers each of the gaskets 60 and the polarizer 40.

In some embodiments, each of the gaskets 60 completely covers a portion of the non-display region 32 of the display panel 30 except the connection region 321.

It may be seen from the above, the present disclosure prevents an occurrence of a mismatch at the clearance region of the display panel, thereby avoiding an effect to a touch function layer bonding or a glass cover bonding, and avoiding problems such as reductions in yield that may cause at a COF press-fit connection, by providing the gaskets at the clearance regions of the display panel.

The OLED display structure and the OLED display screen provided by the embodiments of the present disclosure are described in detail. Principles and embodiments of the present disclosure are herein described in detail. The description of the above embodiments is only for helping to understand the present disclosure. Meanwhile, for those skilled in the art, according to ideas of the present disclosure, there will be changes in specific embodiments and applications. In conclusion, the content of the specification should not be construed as limiting of the present disclosure.

What is claimed is:

1. An organic light emitting diode (OLED) display structure, comprising:
a display panel including a display region and a non-display region, wherein the non-display region comprises a connection region and a plurality clearance regions located on two sides of the connection region;
a polarizer covering the display region;
a chip on film (COF) circuit board assembly having a connection portion, wherein the connection portion covers the connection region to electrically connect to the display panel;
a plurality of gaskets covering the clearance regions; and
a functional assembly disposed over the polarizer, the connection portion, and the gaskets;
wherein each of the gaskets comprises a polyethylene terephthalate (PET) material and a pressure sensitive adhesive (PSA); and wherein the functional assembly comprises a first adhesive layer and a functionality layer adhered to the polarizer via the first adhesive layer.

2. The OLED display structure as claimed in claim 1, wherein the first adhesive layer overlaps with the polarizer, and a thickness of each of the gaskets is greater than or equal to a sum of a thickness of the first adhesive layer and a thickness of the polarizer.

3. The OLED display structure as claimed in claim 1, wherein the first adhesive layer is provided with a notch, the first adhesive layer directly faces the connection region and the clearance regions, the notch directly faces the connection portion, and a thickness of each of the gaskets is equal to a thickness of the polarizer.

4. The OLED display structure as claimed in claim 1, wherein the first adhesive layer directly faces the display panel and a thickness of each of the gaskets is equal to a thickness of the polarizer.

5. The OLED display structure as claimed in claim 1, wherein the functionality layer comprises a touch function layer and/or an optic function layer.

6. The OLED display structure as claimed in claim 1, wherein the polarizer is a circular polarizer.

7. The OLED display structure as claimed in claim 1, wherein the display panel comprises:
a substrate;
a thin film transistor (TFT) array layer disposed on the substrate;
an electroluminescence (EL) layer disposed on the TFT array layer; and
a packaging layer disposed on the EL layer.

8. An organic light emitting diode (OLED) display structure, comprising:
a display panel including a display region and a non-display region, wherein the non-display region comprises a connection region and a plurality of clearance regions located on two sides of the connection region;
a polarizer covering the display region;
a chip on film (COF) circuit board assembly having a connection portion, wherein the connection portion covers the connection region to electrically connect to the display panel;
a plurality of gaskets covering the clearance regions; and
a functional assembly disposed over the polarizer, the connection portion, and the gaskets.

9. The OLED display structure as claimed in claim 8, wherein each of the gaskets comprises a polyethylene terephthalate (PET) material and a pressure sensitive adhesive (PSA).

10. The OLED display structure as claimed in claim 8, wherein the functional assembly comprises a first adhesive layer and a functionality layer adhered to the polarizer via the first adhesive layer.

11. The OLED display structure as claimed in claim 10, wherein the first adhesive layer overlaps with the polarizer, and a thickness of each of the gaskets is greater than or equal to a sum of a thickness of the first adhesive layer and a thickness of the polarizer.

12. The OLED display structure as claimed in claim 10, wherein the first adhesive layer is provided with a notch, the first adhesive layer directly faces the connection region and the clearance regions, the notch directly faces the connection portion, and a thickness of each of the gaskets is equal to a thickness of the polarizer.

13. The OLED display structure as claimed in claim 10, wherein the first adhesive layer directly faces the display panel and a thickness of each of the gaskets is equal to a thickness of the polarizer.

14. The OLED display structure as claimed in claim 10, wherein the functionality layer comprises a touch function layer and/or an optic function layer.

15. The OLED display structure as claimed in claim 8, wherein the polarizer is a circular polarizer.

16. The OLED display structure as claimed in claim 8, wherein the display panel comprises:
a substrate;
a thin film transistor (TFT) array layer disposed on the substrate;
an electroluminescence (EL) layer disposed on the TFT array layer; and
a packaging layer disposed on the EL layer.

17. An organic light emitting diode (OLED) display screen, comprising an OLED display structure, wherein the OLED display structure comprises:
a display panel including a display region and a non-display region, wherein the non-display region comprises a connection region and a plurality of clearance regions located on two sides of the connection region;
a polarizer covering the display region;
a chip on film (COF) circuit board assembly having a connection portion, wherein the connection portion covers the connection region to electrically connect to the display panel;
a plurality of gaskets covering the clearance regions; and
a functional assembly disposed over the polarizer, the connection portion, and the gaskets.

18. The OLED display screen as claimed in claim 17, wherein each of the gaskets comprises a polyethylene terephthalate (PET) material and a pressure sensitive adhesive (PSA).

19. The OLED display screen as claimed in claim 17, wherein the functional assembly comprises a first adhesive layer and a functionality layer adhered to the polarizer via the first adhesive layer.

20. The OLED display screen as claimed in claim 19, wherein the first adhesive layer overlaps with the polarizer, and a thickness of each of the gaskets is greater than or equal to a sum of a thickness of the first adhesive layer and a thickness of the polarizer.
